(19) United States
(12) Patent Application Publication
(10) Pub. No.: US 2023/0416923 A1
(43) Pub. Date: Dec. 28, 2023

(54) SUBSTRATE PROCESSING APPARATUS AND SUBSTRATE PROCESSING SYSTEM HAVING THE SAME

(71) Applicant: WONIK IPS CO., LTD., Pyeongtaek-si Gyeonggi-do (KR)

(72) Inventors: Kee Jun KIM, Osan-si Gyeonggi-do (KR); Seung Ho LEE, Osan-si Gyeonggi-do (KR)

(73) Assignee: WONIK IPS CO., LTD., Pyeongtaek-si Gyeonggi-do (KR)

(21) Appl. No.: 18/081,325

(22) Filed: Dec. 14, 2022

(30) Foreign Application Priority Data
Jun. 28, 2022 (KR) 10-2022-0078901

(51) Int. Cl. C23C 16/54; C23C 16/458; C23C 16/44; C23C 16/52

(52) U.S. Cl. CPC C23C 16/54; C23C 16/458; C23C 16/4412; C23C 16/52

(57) ABSTRACT

The present invention disclosed herein relates to a substrate processing apparatus and a substrate processing system having the same, and more particularly, to a substrate processing apparatus capable of simultaneously processing a large amount of substrates and a substrate processing system having the same. The present invention discloses a substrate processing apparatus including a first processing module in which substrate processing is performed on a plurality of substrates, a second processing module disposed adjacent to the first processing module to perform the substrate processing on the plurality of substrates, a first utility part disposed adjacent to a rear surface of the first processing module, a second utility part disposed adjacent to a rear surface of the second processing module, and an upper support part provided between the first utility part and the second utility part to divide the maintenance space into an upper area and a lower area.

### CROSS-REFERENCE TO RELATED APPLICATIONS

This U.S. non-provisional patent application claims priority under 35 U.S.C. § 119(a) of Korean Patent Application No. 10-2022-0078901, filed on Jun. 28, 2022, in the Korean Intellectual Property Office, the entire contents of which are hereby incorporated by reference.

### FIELD OF THE INVENTION

The present invention disclosed herein relates to a substrate processing apparatus and a substrate processing system having the same, and more particularly, to a substrate processing apparatus capable of simultaneously processing a large amount of substrates and a substrate processing system having the same.

### BACKGROUND ART

In order to manufacture a element, a process of depositing a required thin film on a substrate or a process of performing heat processing to modify the deposited thin film are performed. In particular, sputtering, chemical vapor deposition (CVD), and atomic layer deposition (ALD) are mainly used for the thin film deposition process.

The sputtering is a technology in which argon ions generated in a plasma state collide with a surface of a target, and a target material separated from the surface of the target is deposited as a thin film on a substrate. The sputtering may have an advantage of forming a high-purity thin film having excellent adhesion, but there is a limit to form a fine pattern having a high aspect ratio.

The chemical vapor deposition is a technique of depositing a thin film on a substrate by injecting various gases into a reaction chamber and allowing gases induced by high energy such as heat, light, or plasma to chemically react with a reaction gas. Since the chemical vapor deposition uses the chemical reaction that occurs quickly, it is very difficult to control thermodynamic stability of atoms, and there is a limitation in that physical, chemical and electrical properties of the thin film are deteriorated.

The atomic layer deposition is a technology for depositing a thin film in atomic layer units on a substrate by alternately supplying a source gas and a purge gas, which are reaction gases. Since the atomic layer deposition uses surface reaction to overcome a limitation of step coverage, it is suitable for forming a micro pattern with a high aspect ratio and has excellent electrical and physical properties of the thin film.

In spite of the advantages of the atomic layer deposition, there is a limitation in that productivity is deteriorated due to a decrease in substrate processing speed due to the step of alternately supplying a purge gas while supplying a source gas and a reaction gas.

In addition to the above-described deposition process, a process of performing heat processing on individual substrates in the process of heat processing, etc. has a limitation in that productivity is low because a substrate processing speed is lowered according to a loading/unloading time of the substrate.

In order to solve this limitation, a vertical batch type processing module, in which a plurality of substrates are loaded within a chamber to collectively perform the substrate processing, is used.

In addition, in order to further improve the productivity, a processing module, in which the plurality of substrates are vertically loaded to perform the substrate processing at the same time, are provided in plurality to be used.

In such the batch type processing module, since a loading area for loading and unloading substrates are disposed at a lower side, and a substrate processing part for processing a plurality of vertically arranged substrates are disposed at an upper side, there is a limitation in that an installation positions of a substrate processing part and an auxiliary component that supplies and exhausts various gases into/from the substrate processing part are high to cause a limitation, in which a worker has to perform installation and working with a ladder in a narrow space for maintenance.

Particularly, since it is difficult to install a tool for maintenance such as ladders placed in a limited space, and it is difficult to secure a work space even after the installation, and also, the work is performed on the ladder, there is a problem in securing the safety of the worker.

In addition, in the conventional substrate processing apparatus, since maintenance of the height corresponding to the loading area and maintenance of the height corresponding to the processing module are not performed at the same time due to the installation of the maintenance tool, there is a limitation in that the maintenance time and space increase.

### SUMMARY OF THE INVENTION

To solve the above-mentioned limitations, the present invention provides a substrate processing apparatus capable of easily and safely performing maintenance on an upper processing module and a substrate processing system having the same.

In accordance with an embodiment of the present invention, disclosed is a substrate processing apparatus including: a first processing module (100) in which substrate processing is performed on a plurality of substrates (1); a second processing module (200) disposed adjacent to the first processing module (100) to perform the substrate processing on the plurality of substrates (1); a first utility part (300) disposed adjacent to a rear surface of the first processing module (100); a second utility part (400) disposed adjacent to a rear surface of the second processing module (200) to define a maintenance space between the second processing module (200) and the first utility unit (300); and an upper support part (500) provided between the first utility part (300) and the second utility part (400) to divide the maintenance space into an upper area (S1) and a lower area (S2).

The first processing module (100) may include: a first substrate processing part (110) disposed at an upper side to process the substrates (1); and a first substrate loading part (120) disposed below the first substrate processing part (110) to load and unload the substrates (1), wherein the second processing module (200) may include: a second substrate processing part (210) disposed at an upper side to process the substrates (1); and a second substrate loading part (220) disposed below the second substrate processing part (210) to load and unload the substrates (1).

The upper support part (500) may be disposed at a height corresponding to a lower side of each of the first substrate processing part (110) and the second substrate processing part (210).

The upper support part (500) may be disposed to be in contact with a rear surface of each of the first processing module (100) and the second processing module (200).

The upper support part (500) may include: a support bracket (520) protruding from the first utility part (300) and the second utility part (400) in opposite directions; and an upper support (510) supported on the support bracket (520).

The upper support part (500) may include: a support frame provided to correspond to an area surrounded by a rear surface of the first processing module (100), a rear surface of the second processing module (200), an inner surface of the first utility part (300), and an inner surface of the second utility part (400); and an upper support (510) supported and installed on the support frame.

The upper support part (500) may include: a frame part installed between the first utility part (300) and the second utility part (400); and a cover part that covers the frame part and is detachably installed.

The upper support part (500) may include a plurality of through-holes (501) that are penetrated in a vertical direction.

In the first utility part (300), an outer surface opposite to a direction in which the second utility part (400) is disposed may be disposed on the same plane as an opposite surface of the first processing module (100) to a direction in which the second processing module (200) is disposed, and in the second utility part (400), an outer surface opposite to a direction in which the first utility part (300) is disposed may be disposed on the same plane as an opposite surface of the second processing module (200) to a direction in which the first processing module (100) is disposed.

The first utility part (300) may include: a first gas supply part (310) configured to supply a gas to the first processing module (100); a first gas exhaust part (320) configured to exhaust the gas from the first processing module (100); and a first control part (330) disposed above the first gas supply part (310) and the first gas exhaust part (320) to control the first processing module (100), wherein the second utility part (400) may include: a second gas supply part (410) configured to supply a gas to the second processing module (200); a second gas exhaust part (420) configured to exhaust the gas from the second processing module (200); and a second control part (430) disposed above the second gas supply part (410) and the second gas exhaust part (420) to control the second processing module (200).

The upper support part (500) may have one end disposed at a height corresponding to a boundary between the first gas supply part (310), the first gas exhaust part (320), and the first control part (330), and the other end disposed at a height corresponding to a boundary between the second gas supply part (410), the second gas exhaust part (420), and the second control part (430).

The substrate processing apparatus may further include a lower support part (600) disposed a bottom surface of the lower area (S2) in the maintenance space between the first utility part (300) and the second utility part (400).

The substrate processing apparatus may further include an auxiliary utility part (800) provided on at least one of the inside and lower side of the upper support part (500) or between the first processing module (100), the second processing module (200), and the upper support part (500).

The auxiliary utility part (800) may have a top surface having the same plane as a top surface of the upper support part (500) between the first processing module (100), the second processing module (200), and the upper support part (500).

The auxiliary utility part (800) may include a valve module (700) configured to control a gas, which is supplied to the first processing module (100) and the second processing module (200) from the first utility part (300) and the second utility part (400), respectively.

The valve module (700) may include: a first valve module connected to the first utility part (300) to supply or block the gas to the first processing module (100) through opening and closing; and a second valve module connected to the second utility part (400) to supply or block the gas to the second processing module (200) through opening and closing.

The auxiliary utility part (800) may include at least one of a purge gas supply part (810) configured to supply a purge gas to the first processing module (100) and the second processing module (200) or an auxiliary control part (820) configured to control a portion of the first processing module (100) and the second processing module (200).

The substrate processing apparatus may further include a plurality of safety bars (900) having one end detachably coupled to a rear surface of the first utility part (300) and the other end detachably coupled to a rear surface of the second utility part (400) at upper heights of the upper support part (500).

In accordance with another embodiment of the present invention, disclosed is a substrate processing system including: a substrate storage module (10) in which a substrate is loaded and stored; a substrate processing apparatus (30), which is configured to process the substrate and has a vertical structure; and a substrate transfer module (20) configured to transfer the substrate between the substrate storage module (10) and the substrate processing apparatus (30).

The substrate transfer module (20) may be disposed adjacent to a front surface of each of the first processing module (100) and the second processing module (200) and be used commonly for the first processing module (100) and the second processing module (200).

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a side view illustrating a configuration of a substrate processing system according to a related art;

FIG. 2 is a side view illustrating a configuration of a substrate processing system according to the present invention;

FIG. 3 is a plan view illustrating the configuration of the substrate processing system of FIG. 2;

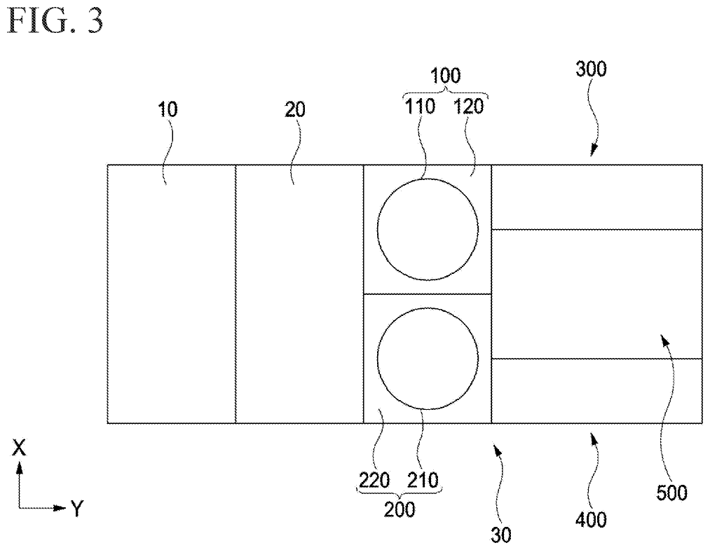

FIG. 4 is a side view illustrating a configuration of a substrate processing system according to the present invention;

FIG. 5 is a cross-sectional view illustrating the configuration of the substrate processing system of FIG. 4, taken along line A-A′;

FIG. 6 is a cross-sectional view illustrating the configuration of the substrate processing system of FIG. 4, taken along line B-B′;

FIG. 7 is a rear view illustrating a configuration of the substrate processing system of FIG. 4; and

FIG. 8 is a rear view illustrating a configuration of a substrate processing system according to another embodiment of the present invention.

### DETAILED DESCRIPTION OF THE PREFERRED EMBODIMENTS

Hereinafter, a substrate processing apparatus and a substrate processing system having the same will be described with reference to the accompanying drawings.

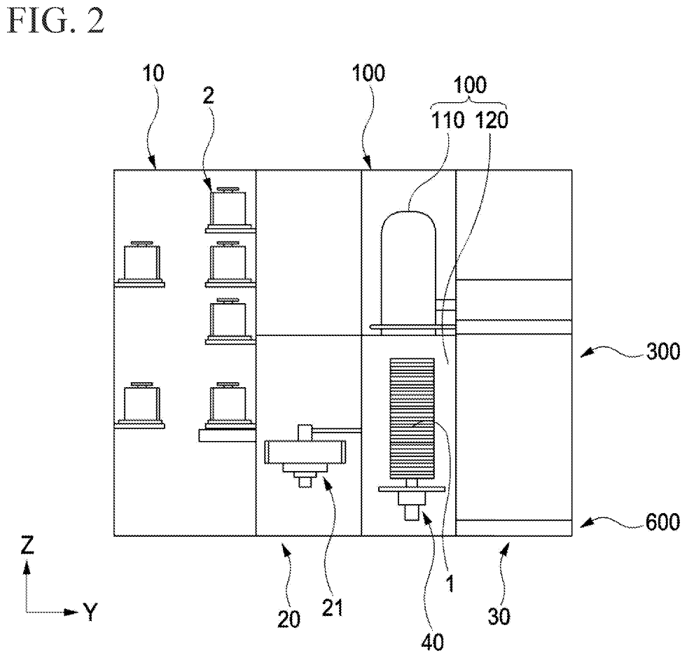

As illustrated in FIG. 2, a substrate processing system according to the present invention includes a substrate storage module 10 in which a substrate is loaded and stored, a substrate processing apparatus 30 that processes the substrate and has a vertical structure, and a substrate transfer module 20 transferring the substrate between the substrate storage module 10 and the substrate processing apparatus 30.

Here, a substrate 1, which is a subject of substrate processing according to the present invention, may be a configuration, on which substrate processing such as deposition, heat processing, and the like is performed, and any substrate such as a semiconductor manufacturing substrate, an LCD manufacturing substrate, an OLED manufacturing substrate, a solar cell manufacturing substrate, and a transparent glass substrate may be applied as the substrate 1.

Particularly, the substrate 1, which is a subject of substrate processing according to the present invention, may be processed simultaneously by stacking 50 or more sheets of substrates 1 in a vertical direction, and for this purpose, the plurality of substrates 1 may be stored and move through a substrate storage part 2 in which the plurality of substrates 1 are stacked.

The substrate storage module 10 is configured to load and store the substrate 1 and may have various configurations.

For example, in a state in which the plurality of substrates 1 are loaded and inserted into the substrate storage part 2, the substrate storage module 10 may take out the substrate storage part 2 from the outside to temporarily store the substrate storage part 2.

In addition, the substrate storage module 10 may take out the substrate storage part 2, in which the processed substrates are loaded and inserted, from the inside to the outside.

The substrate storage module 10 may stack and temporarily store the plurality of substrate storage parts 2, in which the substrates to be processed are stored, and the stored substrate storage parts 2 may be transferred to a substrate transfer module 20 to be described later to supply the plurality of substrates so as to perform the process.

The substrate storage module 10 may be disposed in front of the first processing module 100 and the second processing module 200 to be described later and may be provided to respectively correspond to the first processing module 100 and the second processing module 200. For another example, the first processing module 100 and the second processing module 200 may be commonly used to supply the substrates 1 stored in each of the processing modules.

The substrate transfer module 20 may be configured to transfer the substrates between the substrate storage module 10 and the substrate processing apparatus 30 and may have various configurations.

For example, the substrate transfer module 20 may include a substrate transfer part 21 installed therein to transfer the substrates between the substrate storage module 10 and the substrate processing apparatus 30.

That is, in the substrate transfer module 20, a separate chamber having an internal space may be disposed between the substrate storage module 10 and the substrate processing apparatus 30, and the substrate transfer part 21 may be installed inside the chamber to receive the substrates from the substrate storage module 10 and then transfer the substrates to the substrate processing apparatus 30. I.e., each of a first processing module 100 and a second processing module 200 to be described later.

Here, the substrate transfer module 20 may be provided in plurality to correspond to the first processing module 100 and the second processing module 200. For another example, the substrate transfer module 20 may be commonly used for the first processing module 100 and the second processing module 200.

More particularly, the substrate transfer module 20 may be disposed adjacent to a front surface of each of the first processing module 100 and the second processing module 200 and thus may be used commonly for the first processing module 100 and the second processing module 200.

The substrate processing apparatus 30 may be configured to simultaneously process the plurality of substrates 1 and may have a vertical structure.

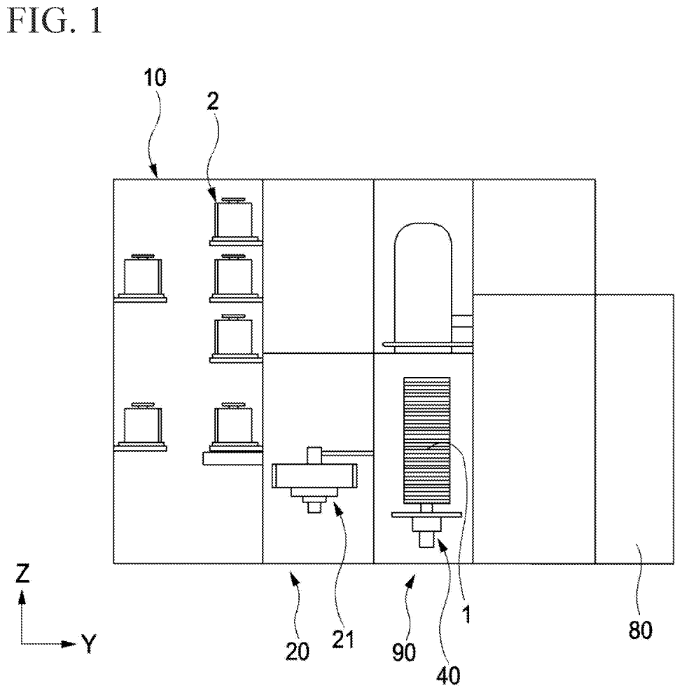

As illustrated in FIG. 1, the substrate processing apparatus according to the related art includes a processing module 90, a first utility part 300 provided on a rear surface of the processing module 90, and a utility 80 additionally provided on a rear surface of the first utility part 300.

That is, the substrate processing apparatus according to the related art has a limitation in that, since the substrate processing apparatus has a long length from the front surface-side substrate storage module 10 to the rear surface-side utility 80, a footprint increases.

When the rear surface-side utility 80 is provided in the first utility part 300, there is a limitation in that a height of the first utility part 300 increases to limit an external installation space, or the first utility part 300 is thick so that a maintenance space becomes narrow.

In addition, in the substrate processing apparatus according to the related art, since a height of a reaction tube configuration disposed at an upper side of the processing module 100 exceeds about 2,800 mm, there is a limitation in that there is a risk of injury due to falling of a worker during the maintenance of the reaction tube and surrounding components, and when using tools such as a jig and ladder for other maintenance, work is limited, and work efficiency is low.

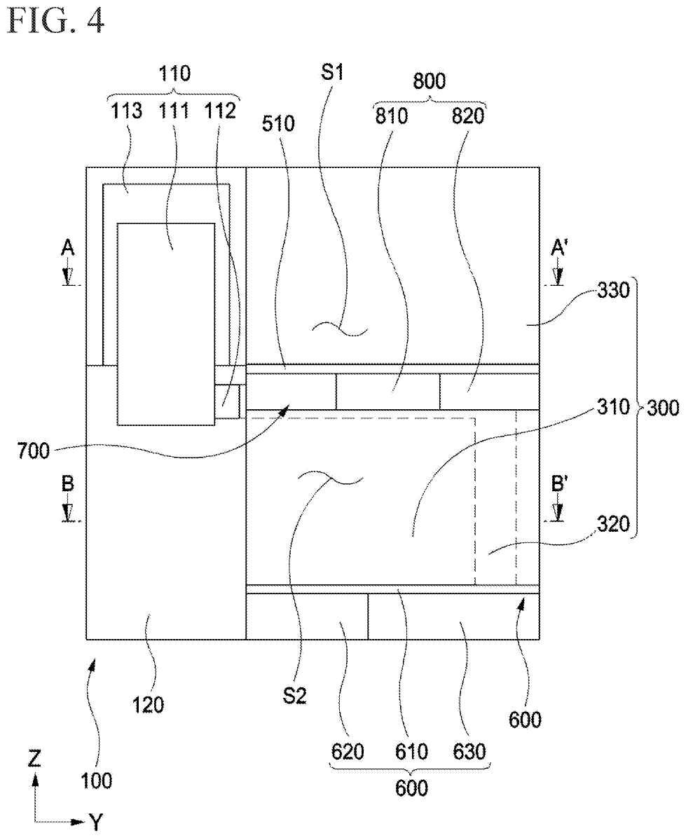

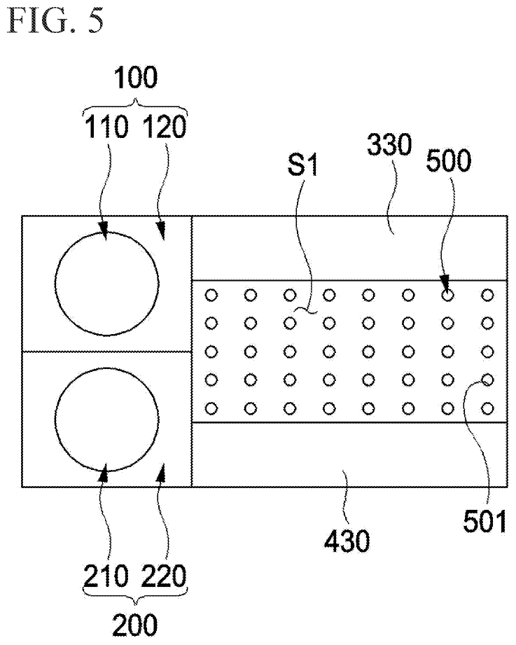

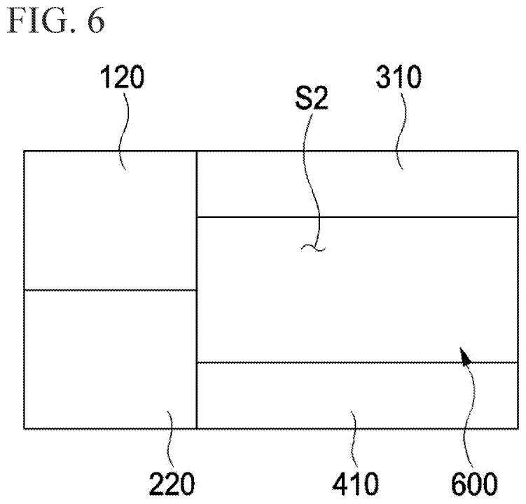

In order to improve these limitations, as illustrated in FIGS. 4 to 7, a substrate processing apparatus according to the present invention includes a first processing module 100 in which substrate processing is performed on a plurality of substrates 1, a second processing module 200 disposed adjacent to the first processing module 100 to perform the substrate processing on the plurality of substrates 1, a first utility part 300 disposed adjacent to a rear surface of the first processing module 100, a second utility part 400 disposed adjacent to a rear surface of the second processing module 200 to define a maintenance space between the second processing module 200 and the first utility unit 300, and an upper support part 500 provided between the first utility part 300 and the second utility part 400 to divide the maintenance space into an upper area S1 and a lower area S2.

The first processing module 100 may be configured to perform the substrate processing on the plurality of substrates 1 and may have various configurations.

For example, the first processing module 100 may include a first substrate processing part 110 disposed at an upper side to process the substrates 1 and a first substrate loading part 120 disposed below the first substrate processing part 110 to load and unload the substrates 1.

Here, the first substrate processing part 110 may include a first reaction tube 111 in which a boat 40 on which the plurality of substrates 1 are stacked is accommodated to perform the substrate processing, a first manifold 112 provided on a lower portion of the first reaction tube 111 and connected to a first gas supply part 310 and a first gas exhaust part 320 to be described later, and a first heater part 113 installed to surround the first reaction tube 111.

The first substrate loading part 120 may be disposed below the first substrate processing part 110 to load and unload the substrates and may have various configurations.

For example, the first substrate loading part 120 may be disposed below the first substrate processing part 110 to ascend to the first substrate processing part 110 so as to load the substrates 1 to be processed or to unload the processed substrates 1 descending from the first substrate processing part 110.

For this, the first substrate loading part 120 may include a boat 40 loaded in a shape in which the plurality of substrates 1 are stacked and a boat elevator (not shown) for allowing the boat 40 to ascend to the first substrate processing part 110 disposed at the upper side.

In addition, the first substrate loading part 120 may include a first maintenance door 121 installed on the rear surface of the first substrate loading part 120 so as to be accessible to the inside of the first processing module 100, accessible to a space of the first substrate loading part 120 through the opening and closing, accessible to the first substrate processing part 110 disposed at the upper side through the first substrate loading part 120.

Here, the first maintenance door 121 may be opened and closed through hinge rotation and may be opened by rotating toward the first utility part 300 or by rotating toward the second utility part 400.

The second processing module 200 may be configured to include a second substrate processing part 210 that processes the substrate and to be disposed adjacent to the first processing module 100 and may have various configurations.

That is, the second processing module 200 may have one surface that is in contact with one surface of the first processing module 100 and disposed adjacent to the first processing module 100. Here, the second processing module 200 may be disposed side by side in the same direction as the first processing module 100.

That is, the second processing module 200 may be disposed so that the side surfaces facing each other are in contact with each other in a state in which front and rear surfaces of the first processing module 100 face the same direction.

Like the first processing module 100 described above, the second processing module 200 may include a second substrate processing part 210 disposed at the upper side to define a second processing space for processing the substrates therein and process the plurality of loaded substrates 1 and a second substrate loading part 220 disposed below the second substrate processing part 210 to perform the loading and unloading of the substrates.

Here, the second substrate processing part 210 may include a second reaction tube in which the boat 40 on which the plurality of substrates 1 are stacked is accommodated to perform the substrate processing, a first manifold provided on a lower portion of the second reaction tube and connected to a second gas supply part and a second gas exhaust part 420 to be described later, and a second heater part installed to surround the second reaction tube.

The second substrate loading part 220 may be disposed below the second substrate processing part 210 to load and unload the substrates and may have various configurations.

For example, the second substrate loading part 220 may be disposed below the second substrate processing part 210 to ascend to the second substrate processing part 210 so as to load the substrates 1 to be processed or to unload the processed substrates 1 descending from the second substrate processing part 210.

For this, the second substrate loading part 220 may include a boat 40 loaded in a shape in which the plurality of substrates 1 are stacked and a boat elevator (not shown) for allowing the boat 40 to ascend to the second substrate processing part 210 disposed at the upper side.

The second substrate lading part 220 may include a second maintenance door 221 installed on the rear surface of the second substrate loading part 220 so as to be accessible to the inside of the second processing module 200, accessible to a space of the second substrate loading part 220 through the opening and closing, accessible to the second substrate processing part 210 disposed at the upper side through the second substrate loading part 220.

Here, the second maintenance door 221 may be opened and closed through hinge rotation and may be opened by rotating toward the second utility part 400 or by rotating toward the first utility part 300.

The first utility part 300 may be a configuration that is disposed adjacent to a rear surface of the first processing module 100 and may have various configurations.

For example, the first utility part 300 may include a first gas supply part 310 supplying a gas to the first processing module 100, a first gas exhaust part 320 exhausting the gas from the first processing module 100, and a first control part 330 disposed above the first gas supply part 310 and the first gas exhaust part 320 to control the first processing module 100.

The first gas supply part 310 may be configured to supply a gas to the first processing module 100 and may have various configurations.

For example, the first gas supply part 310 may be connected to the first manifold 112 of the first substrate processing part 110 to supply the gas for the substrate processing. For this, a supply tube and a supply control valve may be installed inside the first gas supply part 310 to be in contact with the rear surface of the first processing module 100.

The first gas exhaust part 320 may be configured to exhaust the inside of the first processing module 100, and more particularly, exhaust the inside of the first reaction tube 111 of the first substrate processing part 110.

For example, the first gas exhaust part 320 may include an exhaust line and an exhaust control valve, which are provided vertically adjacent to the first gas supply part 310 disposed to be in contact with the rear surface of the first processing module 100 in a rear direction and connects an external exhaust pump (not shown) to the first manifold 112 of the first substrate processing part 110 to exhaust the inside of the first substrate processing part 110.

In addition, the first gas exhaust part 320 may further include a pressure control part and various sensors for adjusting a pressure of an exhaust gas discharged through the exhaust line therein.

The first gas exhaust part 320 may be provided in a rectangular parallelepiped shape, like the first gas supply part 310 and may have one surface disposed to be in contact with the rear surface of the first gas supply part 310 and the other surface disposed toward the rear surface of the first processing module 100.

The first control part 330 may be disposed above the first gas supply part 310 and the first gas exhaust part 320 and may have various configurations.

Here, the first control part 330 may be provided with a device for controlling various components of the first processing module 100 including the first substrate processing part 110, for example, a temperature control part, a pressure control part, and the like, which control a temperature and pressure within the first substrate processing part 110.

The first control part 330 may be disposed above the first gas supply part 310 and the first gas exhaust part 320 and may be disposed to be in contact with the rear surface of the first processing module 100.

The first utility part 300 may have an outer surface disposed on a surface of the first processing module 100 that is the same plane as an opposite surface of the second processing module 200 so that the maintenance space is defined between the first utility part 300 and the second utility part 400 to be described later.

That is, the first utility part 300 may be disposed at an outer end so that the opposite side of the second utility part 400 to be described later is disposed on the same plane as the outer surface of the first processing module 100.

The second utility part 400 may be disposed adjacent to the rear surface of the second processing module 200 to define the maintenance space between the first utility part 300 and the second utility part 400 and may have various configurations.

For example, the second utility part 400 may include a second gas supply part 410 supplying a gas to the second processing module 200, a second gas exhaust part 420 exhausting the gas from the second processing module 200, and a second control part 430 disposed above the second gas supply part 410 and the second gas exhaust part 420 to control the second processing module 200.

The second gas supply part 410 may be configured to supply the gas to the second processing module 200 and may have various configurations.

For example, the second gas supply part 410 may be connected to the second manifold of the second substrate processing part 210 to supply the gas for the substrate processing. For this, a supply tube and a supply control valve may be installed inside the second gas supply part 410 to be in contact with the rear surface of the second processing module 200.

The second gas exhaust part 420 may be configured to exhaust the inside of the second processing module 200, and more particularly, exhaust the inside of the second reaction tube the second substrate processing part 210.

For example, the second gas exhaust part 420 may include an exhaust line and an exhaust control valve, which are provided vertically adjacent to the second gas supply part 410 disposed to be in contact with the rear surface of the second processing module 200 in a rear direction and connects an external exhaust pump (not shown) to the second manifold of the second substrate processing part 210 to exhaust the inside of the second substrate processing part 210.

In addition, the second gas exhaust part 420 may further include a pressure control part and various sensors for adjusting a pressure of an exhaust gas discharged through the exhaust line therein.

The second gas exhaust part 420 may be provided in a rectangular parallelepiped shape, like the second gas supply part 410 and may have one surface disposed to be in contact with the rear surface of the second gas supply part 410 and the other surface disposed toward the rear surface of the second processing module 200.

The second control part 430 may be disposed above the second gas supply part 410 and the second gas exhaust part 420 and may have various configurations.

Here, the second control part 430 may be provided with a device for controlling various components of the second processing module 200 including the second substrate processing part 210, for example, a temperature control part, a pressure control part, and the like, which control a temperature and pressure within the second substrate processing part 210.

The second control part 430 may be disposed above the second gas supply part 410 and the second gas exhaust part 420 and may be disposed to be in contact with the rear surface of the second processing module 200.

The second utility part 400 may have an outer surface disposed on a surface of the second processing module 200 that is the same plane as an opposite surface of the first processing module 100 so that the maintenance space is defined between the first utility part 300 and the second utility part 400 to be described later.

That is, the second utility part 400 may be disposed at an outer end so that the opposite side of the first utility part 300 to be described later is disposed on the same plane as the outer surface of the second processing module 200.

The upper support part 500 may be provided between the first utility part 300 and the second utility part 400 to divide the maintenance space into an upper area S1 and a lower area S2 and may have various configurations.

That is, the upper support part 500 may enhance maintenance accessibility to the first substrate processing part 110 and the second substrate processing part 210, which are disposed at a relatively high position, and may be provided with the first utility part 300 and the second utility part 400 so as to be applied as a foothold for a worker, thereby securing safe and easy working environments.

For this, the upper support part 500 may be disposed at a height corresponding to a lower side of each of the first substrate processing part 110 and the second substrate processing part 210 so as to facilitate access to components disposed at an upper side.

That is, the upper support part 500 may be disposed at a height corresponding to the first manifold 112 so that access and maintenance to the first control part 330, the second control part 430, the first substrate processing part 110, and the second substrate processing part 210 are possible.

In addition, for another example, the upper support part 500 may have one end disposed at a height corresponding to a boundary between the first gas supply part 310, the first gas exhaust part 320, and the first control part 330, and the other end disposed at a height corresponding to a boundary between the second gas supply part 410, the second gas exhaust part 420, and the second control part 430.

That is, the upper support part 500 may be disposed at the height corresponding to the boundary between the first gas supply part 310, the first gas exhaust part 320, and the first control part 330 to divide the maintenance space into an upper area S1 surrounded by the first control part 330 and the second control part 430 and a lower area S2 surrounded by the first gas supply part 310, the first gas exhaust part 320, the second gas supply part 410, and the second gas exhaust part 420.

Here, in the upper support part 500, each of the first control part 330 and the second control part 430 may have a thickness less than that of each of the first gas supply part 310, the first gas exhaust part 320, the second gas supply part 410 so that one end thereof is supported on a top surface of each of the first gas supply part 310 and the first gas exhaust part 320, and the other end thereof is supported on a top surface of each of the second gas supply part 410 and the upper surface of the exhaust part 420.

In addition, in the upper support part 500, a separate bracket 520 may be installed at each of the height corresponding to the boundary between the first gas supply part 310, the first gas exhaust part 320, and the first control part 330 and the height corresponding to the boundary between the second gas supply part 410, the second gas exhaust part 420, and the second control part 430 so that the upper support 510 is supported and installed.

In the inside of the Fab in which the substrate processing apparatus is installed, particles may be typically exhausted by generating an airflow from a ceiling side to a floor side, and the first utility part 300 and the second utility part 400 may be disposed so that the first gas exhaust unit 320 and the second gas exhaust unit 420, which provide exhaust-related utilities, respectively, are disposed at positions adjacent to the bottom side.

Furthermore, since various tubes for the gas supply and the gas exhaust are also installed on the bottom inside the Fab to be stable and minimize external exposure, the first gas supply part 310, the first gas exhaust part 320, the second gas supply part 410, and the second gas exhaust part 420, which require installation of various tubes, are disposed on the bottom area S2, and the configuration of the first control part 330 and the second control part 430, which have a relatively high degree of freedom with respect to the installation position, may be disposed on a side of the upper area S1, which is capable of minimizing the footprint as an extra space.

Thus, in the configuration of the first utility part 300 and the second utility part 400, which are disposed vertically, the upper support part 500 may be disposed at the boundary between the first gas supply part 310, the first gas exhaust part 320, and the first control part 330, and thus, the first control part 330 and the first gas supply part 310 and the first gas exhaust part 320, which are the remaining components, may be separated so that the maintenance is performed for each module.

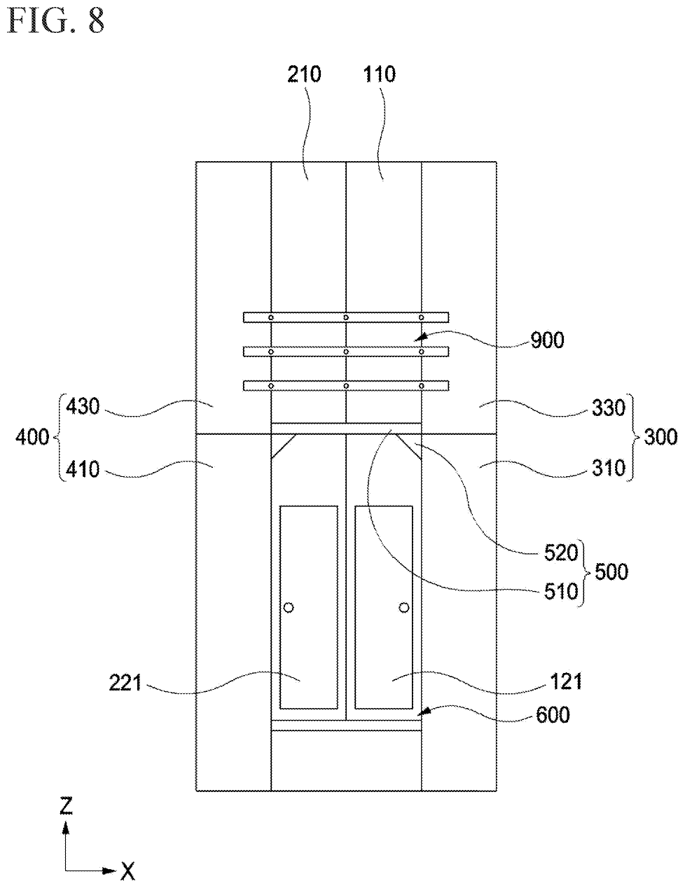

For another example, as illustrated in FIG. 8, the upper support part 500 may include support brackets 520 protruding from the first utility unit 300 and the second utility unit 400 in opposite directions and an upper support 510 supported on the support bracket 520.

That is, the upper support part 500 may include support brackets 520 protruding from the first utility part 300 and the second utility part 400 in opposite directions so that the upper support 510 is installed to be supported through the support bracket 520.

Here, the support bracket 520 may be installed to have a length in the horizontal direction to the first utility part 300 and the second utility part 400 to support the upper support 510 and may be coupled through bolt coupling.

For another example, the upper support part 500 may be configured so that the upper support 510 is supported on a support frame provided to correspond to an area surrounded by a rear surface of the first processing module 100, a rear surface of the second processing module 200, an inner surface of the first utility part 300, and an inner surface of the second utility part 400.

Here, the support frame may be provided as a support frame crossing the first utility part 300 and the second utility part 400 at the rear side of the upper support 510 to more stably support the upper support 510.

Since the upper support 510 may be provided between the first utility part 300 and the second utility part 400 to support the worker and thus may be made of a material having sufficient rigidity.

Particularly, the upper support 510 may include a plurality of through-holes 501 that are penetrated vertically so that an airflow is generated downward from the inside of a clean room in which the substrate processing apparatus is installed to inject an injected cleaning gas into the lower area S2 of the maintenance space.

That is, the cleaning gas injected downward from the upper side may pass through the through-hole 501 to reach the lower area S2 and be induced to be exhausted, thereby smoothly performing the cleaning of the lower area S2.

Therefore, the upper support 510 may be a configuration in which the plurality of through-holes 501 are defined, and thus, even in a state in which the plurality of through-holes 501 are defined, the upper support 510 may be made of a material having sufficient rigidity to withstand a worker's load.

In addition, for another example, the upper support part 500 may include a frame part installed between the first utility part 300 and the second utility part 400 and a cover part that covers the frame part and is detachably installed.

That is, the upper support part 500 may include a frame part of which the inside is penetrated and provided between the first utility part 300 and the second utility part 400 for the supporting, and a cover part that covers a plane of the frame part and is detachably installed, and since the worker removes the upper support part 500 by detaching the cover part, an upper side of each of the first utility part 300, the second utility part 400, and an auxiliary utility unit 800 to be described below may be exposed to the worker.

As a result, the worker may remove the cover part covering at least a portion of the plane of the frame part in a state of being placed on the upper support part 500 to expose the first gas supply unit 310, the first gas exhaust unit 320, the second gas supply unit 410, the second gas exhaust unit 420, and the auxiliary utility unit 800 including the valve module 700, thereby performing the maintenance.

The upper support part 500 may be disposed to be in contact with the rear surfaces of the first processing module 100 and the second processing module 200. For another example, the upper support part 500 may be disposed partially spaced apart from each other in the rear direction.

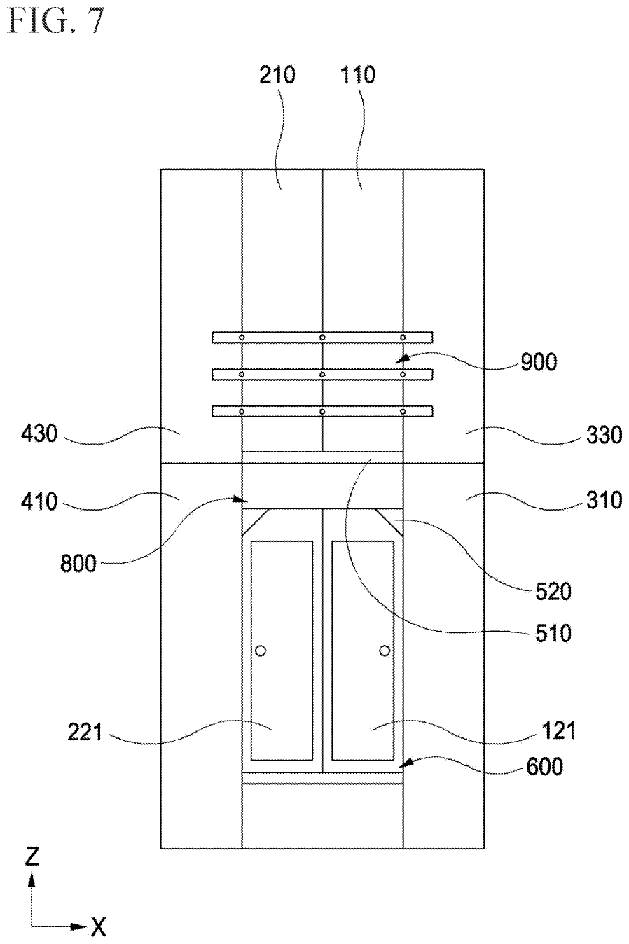

Here, as illustrated in FIG. 7, the substrate processing apparatus according to the present invention may further include an auxiliary utility part 800 provided on at least one of the inside and lower side of the upper support part 500 or between the first processing module 100, the second processing module 200, and the upper support part 500.

That is, the auxiliary utility part 800 may be a configuration that is disposed separately from the first utility part 300 and the second utility part 400 and does not have a large spatial volume and also be provided on at least one of the inside and lower side of the upper support part 500 or between the first processing module 100, the second processing module 200, and the upper support part 500 to decrease in footprint.

Furthermore, the auxiliary utility part 800 may be disposed at a position adjacent to the upper support part 500 as a space for the worker to work during the maintenance to facilitate the maintenance.

Here, the auxiliary utility part 800 may assist in performing of the functions of the first utility part 300 and the second utility part 400 to provide an auxiliary utility to first processing module 100 and the second processing module 200.

Here, the auxiliary utility part 800 may be a configuration that is spaced apart from the first utility part 300 and the second utility part 400, which are installed without changing in configuration of the first utility part 300 and second utility part 400 according to the related art or may be a configuration that is separated from the first utility part 300 and the second utility part 400.

In addition, since the auxiliary utility part 800 is disposed adjacent to the first utility part 300 and the second utility part 400, the auxiliary utility part 800 may be a configuration that is installed to be connected to the first utility part 300 and the second utility part 400.

For example, the auxiliary utility part 800 may include at least one of a valve module 700 controlling a gas supplied to each of the first processing module 100 and the second processing module 200, a first processing module 100 supplying a purge gas to the first processing module 100 and the second processing module 200, or an auxiliary control part 820 controlling a portion of the first processing module 100 and the second processing module 200.

The auxiliary utility part 800 may include a valve module 700 as a final valve that finally regulates the gas supplied to a valve module 700 that needs to be disposed adjacent to all of the first processing module 100, the second processing module 200, the first utility part 300, and the second utility part 400, in particular, the first processing module 100 and the second processing module 200.

The valve module 700 may be configured to control the gas supplied from the first utility part 300 and the second utility part 400 to the first processing module 100 and the second processing module 200 and may have various configurations.

For example, the valve module 700 may be provided inside or below the upper support part 500 when the upper support part 500 is disposed to be in contact with the first processing module 100 and the second processing module 200, more preferably, may be provided at a position adjacent to the first processing module 100 and the second processing module 200.

In addition, when the upper support part 500 is installed to be spaced apart from the first processing module 100 and the second processing module 200, the valve module 700 may be provided between the first processing module 100 and the second processing module 500.

In this case, the valve module 700 may also act as a foothold for the worker together with the upper support part 500 to act as a portion of the configurations for providing working environments and thus may be provided with a housing sufficient rigidity, and furthermore, a top surface of the housing may be provided with the same plane as a top surface of the upper support part 500.

That is, the valve module 700 may be provided between the first processing module 100, the second processing module 200, and the upper support part 500, and thus, their top surfaces may have the same plane. Thus, the valve module 700 may function as a support for the worker to work, that is, an extension of the upper support part 500 to improve the worker's work convenience, and the valve module 700 may be installed in an optimal position adjacent to the first processing module 100 and the second processing module 200 without the need to secure a separate installation space for the valve module 700.

For another example, a high or low height difference between the top surface of the valve module 700 and the top surface of the upper support part 500 may be provided to provide an appropriate working environment.

Here, the valve module 700 may include a first valve module connected to the first gas supply part 310 to supply or block a gas to the first processing module 100 through the opening and closing and a second valve module connected to the second gas supply part 410 to supply or block a gas to the second processing module 200 through the opening and closing.

The auxiliary utility part 800 may be provided inside or below the upper support part 500 to provide the utility for some components of the substrate processing apparatus.

For example, the auxiliary utility part 800 may include a purge gas supply part 810 supplying a purge gas to the first processing module 100 and the second processing module 200 and an auxiliary control part 820 controlling a portion of the first processing module 100 and the second processing module 200.

That is, the auxiliary utility part 800 may be a configuration corresponding to the utility 80 of the substrate processing apparatus according to FIG. 1 according to the related art and may act as a factor that increases in overall footprint. Thus, the auxiliary utility part 800 may be provided inside or below the upper support part 500 to decrease in overall footprint.

Here, as illustrated in FIGS. 4 and 7, the auxiliary utility part 800 may be disposed below the upper support part 500, and when the valve module 700 is installed, the auxiliary utility part 800 may be disposed from the valve module 700 toward the rear surface.

When the auxiliary utility part 800 is installed, a plurality of through-holes 501 defined in the upper support 510 may be defined to avoid the position at which the auxiliary utility part 800 is installed.

In addition, unlike the above-described examples, the auxiliary utility part 800 may be configured so that a portion of the first utility part 300 and the second utility part 400 are provided inside or below the upper support part 500. Thus, a width of each of the first utility part 300 and the second utility part 400 may be reduced to additionally secure the maintenance space or reduce the height.

Furthermore, since the auxiliary utility part 800 and the valve module 700 are disposed inside or below the upper support part 500, it is easier to access the lower area S2 using a maintenance tool such as a simple scaffold, and thus, the maintenance is easy.

The lower support part 600 may be a configuration that is disposed on the bottom surface of the lower area S2 of the maintenance space between the first utility part 300 and the second utility part 400 and may have various configurations.

The lower support part 600 may include a lower support 610 installed with sufficient rigidity, a gas box 620 provided inside or below the lower support 610 to supply a gas to each of the first processing module 100 and the second processing module 200, and an auxiliary control part 630.

The safety bar 900 may be a configuration that is installed with one end detachably coupled to the rear surface of the first utility part 300 and the other end detachably coupled to the rear surface of the second utility part 400 at the upper heights of the upper support part 500 and may be provided in plurality in the vertical direction.

Thus, the safety bar 900 may be detachably provided and installed to across the first utility part 300 and the second utility part 400 during the operation, thereby preventing the worker from falling or dropping.

In addition, a plurality of safety rings may be provided in the first control part 330 and the second control part 430 so as to be connected to the fall prevention line provided in the worker's work clothes, thereby preventing the worker from falling.

In the substrate processing apparatus and the substrate processing system including the same according to the present invention, the stable working environment and the easy access may be provided to the first and second substrate processing parts disposed at the relatively high positions, and thus, there may be the advantage that the operator performs the safe and precise maintenance.

In addition, in the substrate processing apparatus and the substrate processing system including the same according to the present invention, there may be the advantage in that the operator's safety for the maintenance on the configuration disposed at the relatively high position is secured, and the space for installing the existing tools is utilized by omitting the installation of the tools for separate maintenance.

In addition, in the substrate processing apparatus and the substrate processing system including the same according to the present invention, since the installation of the tools for the separate maintenance is omitted, and the maintenance on the upper and lower areas is performed simultaneously, it may be the advantage of the quick maintenance.

In addition, in the substrate processing apparatus and the substrate processing system including the same according to the present invention, since some components in the upper support are disposed, there may be the advantage of reducing the overall length of the apparatus and preventing the increase in width to reduce the footprint and secure the relatively large maintenance space.

Although the above description merely corresponds to some exemplary embodiments that may be implemented by the present invention, as well known, the scope of the present invention should not be interpreted as being limited to the above-described embodiments, and all technical spirits having the same basis as that of the above-described technical spirit of the present invention are included in the scope of the present invention.

What is claimed is:

1. A substrate processing apparatus comprising:
a first processing module in which substrate processing is performed on a plurality of substrates;
a second processing module disposed adjacent to the first processing module to perform the substrate processing on the plurality of substrates;
a first utility part disposed adjacent to a rear surface of the first processing module;
a second utility part disposed adjacent to a rear surface of the second processing module to define a maintenance space between the second processing module and the first utility unit; and
an upper support part provided between the first utility part and the second utility part to divide the maintenance space into an upper area and a lower area.

2. The substrate processing apparatus of claim 1, wherein the first processing module comprises:
a first substrate processing part disposed at an upper side to process the substrates; and
a first substrate loading part disposed below the first substrate processing part to load and unload the substrates,
wherein the second processing module comprises:
a second substrate processing part disposed at an upper side to process the substrates; and
a second substrate loading part disposed below the second substrate processing part to load and unload the substrates.

3. The substrate processing apparatus of claim 2, wherein the upper support part is disposed at a height corresponding to a lower side of each of the first substrate processing part and the second substrate processing part.

4. The substrate processing apparatus of claim 1, wherein the upper support part is disposed to be in contact with a rear surface of each of the first processing module and the second processing module.

5. The substrate processing apparatus of claim 1, wherein the upper support part comprises:
a support bracket protruding from the first utility part and the second utility part in opposite directions; and
an upper support supported on the support bracket.

6. The substrate processing apparatus of claim 1, wherein the upper support part comprises:
a support frame provided to correspond to an area surrounded by a rear surface of the first processing module, a rear surface of the second processing module, an inner surface of the first utility part, and an inner surface of the second utility part; and
an upper support supported and installed on the support frame.

7. The substrate processing apparatus of claim 1, wherein the upper support part comprises:
a frame part installed between the first utility part and the second utility part; and
a cover part that covers the frame part and is detachably installed.

8. The substrate processing apparatus of claim 1, wherein the upper support part comprises a plurality of through-holes that are penetrated in a vertical direction.

9. The substrate processing apparatus of claim 1, wherein, in the first utility part, an outer surface opposite to a direction in which the second utility part is disposed is disposed on the same plane as an opposite surface of the first processing module to a direction in which the second processing module is disposed, and
in the second utility part, an outer surface opposite to a direction in which the first utility part is disposed is disposed on the same plane as an opposite surface of the second processing module to a direction in which the first processing module is disposed.

10. The substrate processing apparatus of claim 1, wherein the first utility part comprises:
a first gas supply part configured to supply a gas to the first processing module;
a first gas exhaust part configured to exhaust the gas from the first processing module; and
a first control part disposed above the first gas supply part and the first gas exhaust part to control the first processing module,
wherein the second utility part comprises:
a second gas supply part configured to supply a gas to the second processing module;
a second gas exhaust part configured to exhaust the gas from the second processing module; and
a second control part disposed above the second gas supply part and the second gas exhaust part to control the second processing module.

11. The substrate processing apparatus of claim 10, wherein the upper support part has one end disposed at a height corresponding to a boundary between the first gas supply part, the first gas exhaust part, and the first control part, and the other end disposed at a height corresponding to a boundary between the second gas supply part, the second gas exhaust part, and the second control part.

12. The substrate processing apparatus of claim 1, further comprising a lower support part disposed a bottom surface of the lower area in the maintenance space between the first utility part and the second utility part.

13. The substrate processing apparatus of claim 1, further comprising an auxiliary utility part provided on at least one of the inside and lower side of the upper support part or between the first processing module, the second processing module, and the upper support part.

14. The substrate processing apparatus of claim 13, wherein the auxiliary utility part has a top surface having the same plane as a top surface of the upper support part between the first processing module, the second processing module, and the upper support part.

15. The substrate processing apparatus of claim 13, wherein the auxiliary utility part comprises a valve module configured to control a gas, which is supplied to the first processing module and the second processing module from the first utility part and the second utility part, respectively.

16. The substrate processing apparatus of claim 15, wherein the valve module comprises:
a first valve module connected to the first utility part to supply or block the gas to the first processing module through opening and closing; and
a second valve module connected to the second utility part to supply or block the gas to the second processing module through opening and closing.

17. The substrate processing apparatus of claim 13, wherein the auxiliary utility part comprises at least one of a purge gas supply part configured to supply a purge gas to the first processing module and the second processing module or an auxiliary control part configured to control a portion of the first processing module and the second processing module.

18. The substrate processing apparatus of claim 1, further comprising a plurality of safety bars having one end detachably coupled to a rear surface of the first utility part and the other end detachably coupled to a rear surface of the second utility part at upper heights of the upper support part.

19. A substrate processing system comprising:
a substrate storage module in which a substrate is loaded and stored;
a substrate processing apparatus comprising:
a first processing module in which substrate processing is performed on a plurality of substrates;
a second processing module disposed adjacent to the first processing module to perform the substrate processing on the plurality of substrates;
a first utility part disposed adjacent to a rear surface of the first processing module;
a second utility part disposed adjacent to a rear surface of the second processing module to define a maintenance space between the second processing module and the first utility unit; and
an upper support part provided between the first utility part and the second utility part to divide the maintenance space into an upper area and a lower area,
wherein the substrate processing apparatus is configured to process the substrate and has a vertical structure; and
a substrate transfer module configured to transfer the substrate between the substrate storage module and the substrate processing apparatus.

20. The substrate processing system of claim 19, wherein the substrate transfer module is disposed adjacent to a front surface of each of the first processing module and the second processing module and is used commonly for the first processing module and the second processing module.
